(19) United States
(12) Patent Application Publication
(10) Pub. No.: US 2026/0107500 A1
(43) Pub. Date: Apr. 16, 2026

(54) SIC MOSFET AND METHOD OF MANUFACTURING THE SAME

(71) Applicant: UNITED MICROELECTRONICS CORP., Hsin-Chu City (TW)

(72) Inventors: Chuang-Han Hsieh, Tainan City (TW); Kai-Lin Lee, Kinmen County (TW); Wei-Jen Chen, Tainan City (TW)

(73) Assignee: UNITED MICROELECTRONICS CORP., Hsin-Chu City (TW)

(21) Appl. No.: 18/963,718

(22) Filed: Nov. 28, 2024

(30) Foreign Application Priority Data
Oct. 14, 2024 (TW) 113138944

(51) Int. Cl. H01L 29/78; H01L 29/06; H01L 29/10; H01L 29/16; H01L 29/66

(52) U.S. Cl. CPC H10D 30/66; H10D 12/031; H10D 30/611; H10D 62/105; H10D 62/393; H10D 62/8325

(57) ABSTRACT

A SiC MOSFET is provided in the present invention, including a SiC substrate, a gate oxide layer on the SiC substrate, an isolation oxide layer on the gate oxide layer, two gates respectively on the gate oxide layer at both sides of the isolation oxide layer, wherein the two gates are both provided with an extending part extending inwardly on the isolation oxide layer, two sources respectively in the SiC substrate at both sides of the gate oxide layer, and a drain contact metal on the other side of the SiC substrate opposite to the gate oxide layer.

### BACKGROUND OF THE INVENTION

### 1. Field of the Invention

The present invention generally relates to a silicon carbide metal oxide semiconductor field effect transistor (SiC MOSFET), and more specifically, to a SiC MOSFET having split gates and method of manufacturing the same.

### 2. Description of the Prior Art

Silicon carbide (SiC) is a third-generation semiconductor material with wide bandgap. It has better physical and chemical properties than traditional silicon (Si), such as high power, high switching frequency, low switching loss, high temperature resistance, high breakdown voltage and high current density, etc., thus it can be widely used in electronic systems that require high frequency, high power density and high reliability, including power conversion systems for electric vehicles, power converters such as inverters, chargers and uninterruptible power supplies (UPS), energy management systems and industrial drive systems, etc., which play an important role increasingly in high-performance electronic equipment.

Metal oxide semiconductor field effect transistor devices made of silicon carbide materials (which will be referred hereinafter as SiC MOSFETs) are expected to replace current commonly used insulated gate bipolar transistor (IGBT) power components. In addition to high voltage resistance, high-frequency driving and low on-resistance, it can significantly reduce switching losses and facilitate chip miniaturization. However, although SiC MOSFET has many advantages as described above, its ability to withstand electrostatic breakdown and short circuit is poor. This is partly due to the small chip area and high current density of SiC MOSFET, which makes the electric field at gate area too high during operation, and the gate oxide layer at interface will easily degrade and fail, causing reliability issues. Accordingly, those skilled in the art must improve the structure of SiC MOSFET, in hope of solving the aforementioned problems.

### SUMMARY OF THE INVENTION

In the light of the aforementioned problems encountered in conventional skills, the present invention hereby proposes a novel SiC MOSFET structure, featuring the design of split gate, which can significantly reduce the electric field at the interface between gates and gate oxide layer, effectively improving the reliability of SiC MOSFET.

One aspect of the present invention is to provide a SiC MOSFET, including: a SiC substrate; a gate oxide layer on the SiC substrate; an isolation oxide layer on the gate oxide layer; two gates respectively at both sides of the isolation oxide layer in a first direction on the gate oxide layer, wherein the two gates are both provided with an extending part extending in the first direction onto the isolation oxide layer; two sources respectively at both sides of the gate oxide layer in the first direction in the SiC substrate; and a drain contact metal on another side of the SiC substrate opposite to the gate oxide layer.

Another aspect of the present invention is to provide a method of manufacturing a SiC MOSFET, including: providing a SiC substrate with two sources facing each other in a first direction; forming a gate oxide layer on the SiC substrate between the two sources; forming a first gate material layer on the gate oxide layer; performing a first photolithography process to pattern the first gate material layer into two lower gate patterns, the two lower gate patterns are respectively on edge portions of the gate oxide layer at both sides in the first direction; forming an isolation oxide layer between the two lower gate patterns; forming a second gate material layer on the two lower gate patterns and the isolation oxide layer; and performing a second photolithography process to pattern the second gate material layer into two upper gate patterns, the two upper gate patterns are respectively on the two lower gate patterns and both provided with an extending parts extending inwardly in the first direction onto the isolation oxide layer, and the two upper gate patterns and the corresponding two lower gate patterns form a first gate and a second gate, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-section of a SiC MOSFET in accordance with one embodiment of the present invention; and

FIGS. 2-10 are schematic cross-sections illustrating a process flow of manufacturing a SiC MOSFET in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

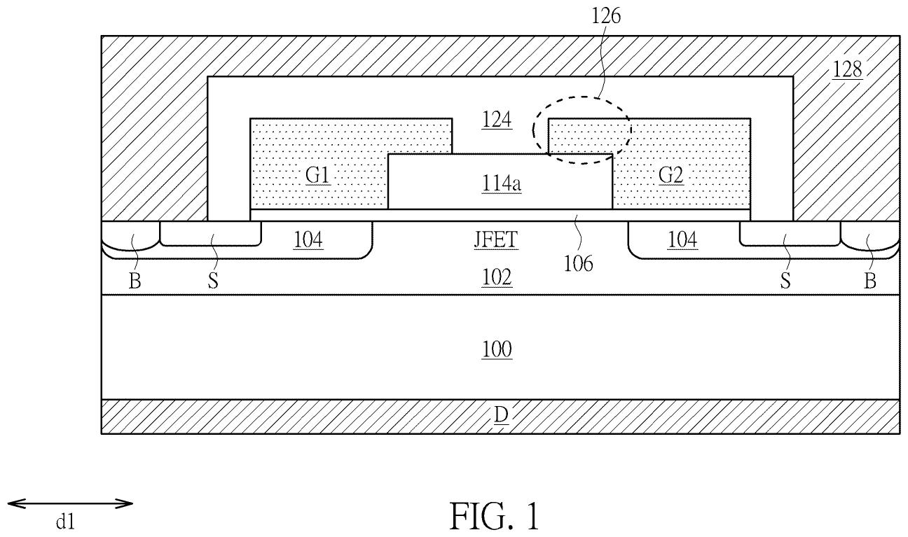

First, please refer to FIG. 1, which is a schematic cross-sectional view of a SiC MOSFET according to one embodiment of the present invention. As shown in the figure, the SiC MOSFET of the present invention includes a substrate 100 as a base for components to be formed thereon. In the embodiment of present invention, the substrate 100 is made of silicon carbide (SiC) with a thickness of about 175 μm, which can be heavily doped (N+) with N-type dopants, such as phosphorus (P) and arsenic (As). The doping concentration is about 1×10¹⁹ cm⁻³ to improve conductivity, reducing the contact resistance of drain terminal and adjust its bandgap. A drain contact metal D (i.e., drain) is provided on the back side of the substrate 100, which is in direct contact with the substrate 100 to output current to an operating voltage. The material of drain contact metal D can be a metal with high conductivity, such as aluminum (Al), nickel (Ni), gold (Au), etc. In another aspect, a drift region 102 is formed on the front side of the substrate 100, which can be grown on the surface of the SiC substrate 100 through an epitaxy process with a thickness of about 12 μm. The drift region 102 may be lightly doped with N-type dopants (N−), with a doping concentration of about 1×10¹⁶ cm⁻³. The thickness and doping concentration of the drift region 102 partially determine the cut-off voltage of the device, and a lower doping concentration can reduce the probability of carrier recombination and ensure that carriers in the device can effectively move and drift under the effect of the electric field, so as to maintain high current density in high voltage environment. It should be noted that in some embodiments, one or more buffer layers (not shown) may be formed between the drift region 102 and the substrate 100 to relieve stress and improve crystal quality. In another aspect, a current spreading layer (not shown) may also be formed on the drift region 102, such as a doping layer with a doping concentration higher than that of the drift region 102, to spread the current laterally and evenly to the horizontal cross-section of the substrate during operation and reduce on-resistance.

Refer still to FIG. 1. A gate oxide layer 106 is formed on the surface of the drift region 102 with a material like silicon oxide or high-k material, such as hafnium oxide (HfO₂) with a thickness of about 40 nm. P-wells 104 are formed in the drift region 102 respectively at both sides of the gate oxide layer 106 in the first direction d1, which can be formed by performing P-type doping process on these areas, such as dopants like boron (B) with a doping concentration of about 1×10¹⁸ cm⁻³ and a depth of about 0.7 μm. The P-type well 104 helps to control the current flow more effectively in the channel of N-type SiC MOSFET device, avoiding the interference between different devices and adjusting the critical voltage of the device. In the embodiment, the P-type well 104 overlaps parts of the gate oxide layer 106 in the vertical direction, and the drift region 102 between the two P-type wells 104 serves as a region of junction gate field effect transistor (JFET) of the device, with a width of about 2 μm, to control the on/off of device channel and improve the switching speed and reduce switching losses of the device. Furthermore, a source S and a base B are also formed in each P-type well 104. In the embodiment, the source S is formed in the P-type well 104 outside the gate oxide layer 106 in the first direction d1 and may partially overlap the gate oxide layer 106 in the vertical direction. The source S may be formed through a heavily N-type doping (N+) to the P-type well 104, with a doping concentration of about 5×10¹⁹ cm⁻³, greater than the doping concentration of the drift region 102, and its depth may be 0.2 μm. The source S functions as an input terminal for current, which may be connected to a reference voltage, such as a ground voltage, through the source contact metal 128. The P-type well 104 between the sources S and the JFET region is a channel region, with a length of about 0.5 μm. The base B may be formed in the P-type well 104 outside the source S in the first direction d1 through a heavy P-type doping (P+) to the P-type well 104, with a doping concentration of about 1×10¹⁹ cm⁻³ larger than the doping concentration of P-type well 104 and a depth of about 0.2 μm. The base B may also be directly connected with the source S. The base B serves as a pick-up terminal of the P-well 104 and can be connected to a reference voltage together with the source S through a source contact metal 128. The pitch of entire device in the first direction d1 may be 14 μm.

Refer still to FIG. 1. As for the components above the gate oxide layer 106 in the embodiment of the present invention, an isolation oxide layer 114a is formed on the gate oxide layer 106. The isolation oxide layer 114a is preferably formed at a middle position of the entire SiC MOSFET device, so that the components and features of the entire device may be in reflection symmetry in the first direction d1 with respect to the center line of the isolation oxide layer 114a. The material of isolation oxide layer 114a may be silicon oxide, with its thickness in the vertical direction smaller than the thickness of the gates G1 and G2 in the vertical direction at both sides. The role of isolation oxide layer 114a in the present invention is to produce split gates (i.e., gates G1 and G2) during the process, which is an important technical feature of the present invention. In the embodiment, the gates G1 and G2 are formed respectively at the both sides of the isolation oxide layer 114a in the first direction d1 on the gate oxide layer 106, with their sidewalls flush with the sidewalls of the gate oxide layer 106 below. The material of gates G1 and G2 may be N-type heavily doped polysilicon. The gates G1 and G2 may partially overlap the corresponding P-type wells 104 and sources S below, where the outer portions outside the gates are sources S and the bases B. In this way, the gates G1 and G2 are arranged on both sides of the device in the form of split gates corresponding to their respective sources S and bases B, and can be connected to a supply voltage of the device through contacts (not shown). In terms of height, the height of the gates G1 and G2 is higher than the height of the central isolation oxide layer 114a, wherein one major feature of the present invention is that both gates G1 and G2 are provided with an extending part 126 inwardly extending in the first direction d1 onto the isolation oxide layer 114a, but the two extending parts 126 do not connected each other.

Refer still to FIG. 1. In the embodiment, a passivation layer 124 is covered on the gates G1 and G2 to provide a protective effect and isolate the gates G1 and G2 from the source contact metal 128 above. The material of passivation layer 124 may be the same as the isolation oxide layer 114a, ex. silicon oxide, which will fill the space between the two extending parts 126 to ensure the gates G1 and G2 isolated. In addition, the passivation layer 124 will expose parts of the surrounding source S areas, so that the sources S can be connected to the source contact metal 128. In the embodiment, the source contact metal 128 may cover and surround the passivation layer 124, as well as being connected to the source S and the base B at both sides at the same time, so as to connect the source S and the base B to an external reference voltage. The material of the source contact metal 128 may be the same as the drain contact metal D at the opposite side of the substrate, such as aluminum (Al), nickel (Ni), gold (Au) and other metals with high conductivity.

In the present invention, the aforementioned design of the special split gates G1 and G2 with the extending parts 126 can change the profile of the electric field at gate region, preventing the electric field from being excessively concentrated in a specific part. Compared with conventional single gate design without extending parts, the electric field at the interface between the gate and the gate oxide layer may be significantly reduced. For example, in a high-temperature gate bias test (HTGB) with a gate voltage of 20V and other terminals grounded, the electric field of the gate oxide layer 106 can be reduced from 4.64 MV/cm to 1.05 MV/cm, and the electric field of the SiC drift region 102 near the gate may be reduced from 0.32 MV/cm to 0.18 MV/cm, which undoubtedly effectively improves resistance to the static electricity and short-circuit and increase the reliability of SiC MOSFET, solving the problems of conventional skill, which is the novelty and non-obviousness the present invention.

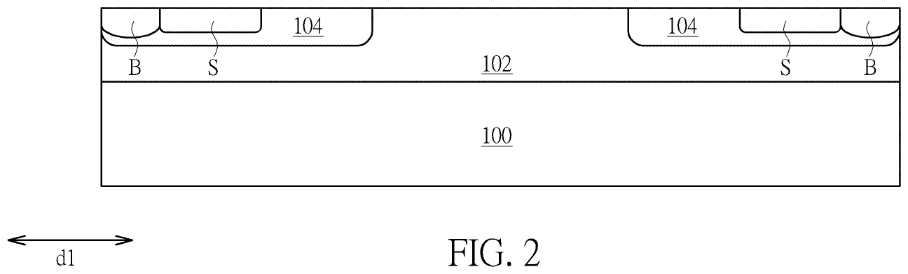

After describing the structure of SiC MOSFET of the present invention, the following embodiments will describe the process of manufacturing the SiC MOSFET of present invention with reference to FIGS. 2-10 in order. These drawings will illustrate the evolution and formation of various components and features of the SiC MOSFET in the present invention during the process in the form of cross-sectional views. Please note that various doped regions mentioned above will be omitted in these figures to avoid obscuring the focus of the present invention.

First, please refer to FIG. 2. At the beginning of the process, a substrate 100 is provided as the basis for the SiC MOSFET device of the present invention. In the embodiment of the present invention, the material of the substrate 100 is silicon carbide (SiC), in which an epitaxial layer functioning as the drift region 102 has been formed in advance through an epitaxy process, and the aforementioned drift region (N−) 102, P-type well (P) 104, source (N+) S, base (P+) and other doped regions are formed therein through ion implantation or diffusion process. The P-type wells 104, the sources S and the bases B on both sides are in reflection symmetry in the first direction d1 with respect to the center line of the device. The doping concentration of the P-type well 104 is about 1×10¹⁸ cm⁻³ with a depth of 0.7 μm. The doping concentration of source S and base B is about 5×10¹⁹ cm⁻³ with a depth of 0.2 μm.

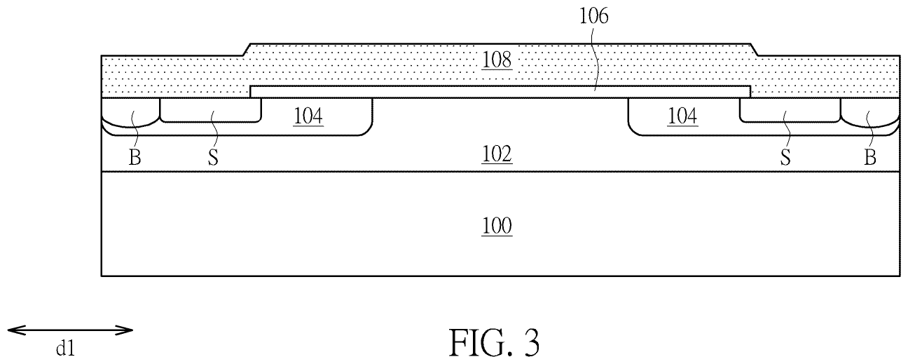

Please refer to FIG. 3. After the aforementioned substrate 100 is prepared, a gate oxide layer 106 and a first gate material layer 108 are sequentially formed on the substrate 100, which can be formed through a CVD process. Among them, the material of gate oxide layer 106 is silicon oxide. Its pattern may be defined through a photolithography process so that both sides of the gate oxide layer 106 in the first direction d1 can partially overlap the P-type wells 104 and the sources S in the vertical direction. The area where the gate oxide layer 106 and the P-type well 104 overlapping is the channel area of the device. The material of the first gate material layer 108 may be N-type heavily doped polysilicon, which covers entire gate oxide layer 106 and the surface of the substrate 100.

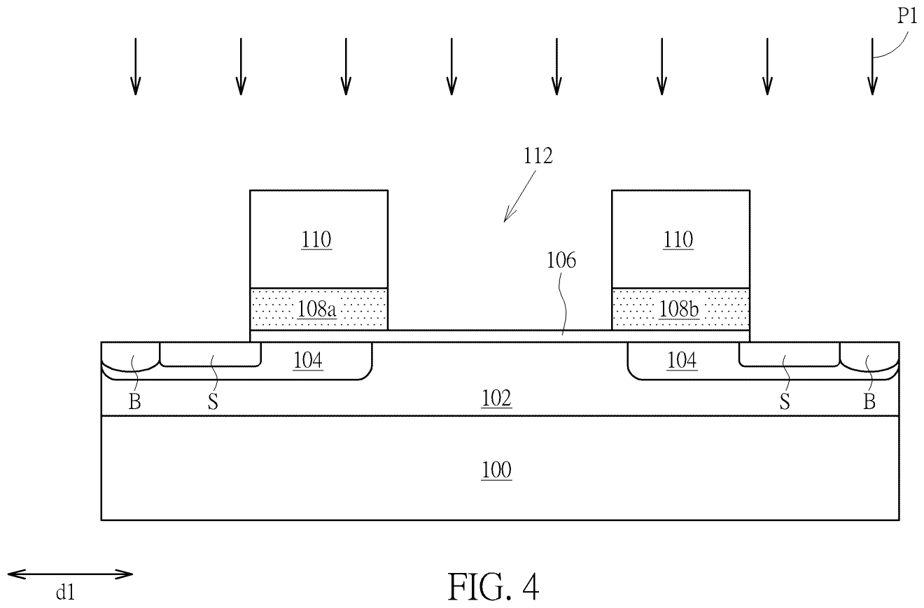

Please refer to FIG. 4. After the gate oxide layer 106 and the first gate material layer 108 are formed, a first photolithography process P1 is performed to remove parts of the first gate material layer 108 to define lower gate patterns 108a and 108b on both sides of the device. More specifically, this step forms a photoresist 110 having a lower gate pattern on the first gate material layer 108 first, and then the photoresist 110 is used as an etching mask to perform an anisotropic etching process to remove the first gate material layer 108 not shielded by the photoresist 110, until the underlying gate oxide layer 106, source S and base B are exposed. The formed lower gate patterns 108a and 108b will be located respectively at both ends of the gate oxide layer 106 in the first direction d1, and their outer sidewalls are preferably flush with the sidewalls of the gate oxide layer 106 below. There will be a space 112 between the lower gate patterns 108a, 108b for subsequent isolation oxide layers.

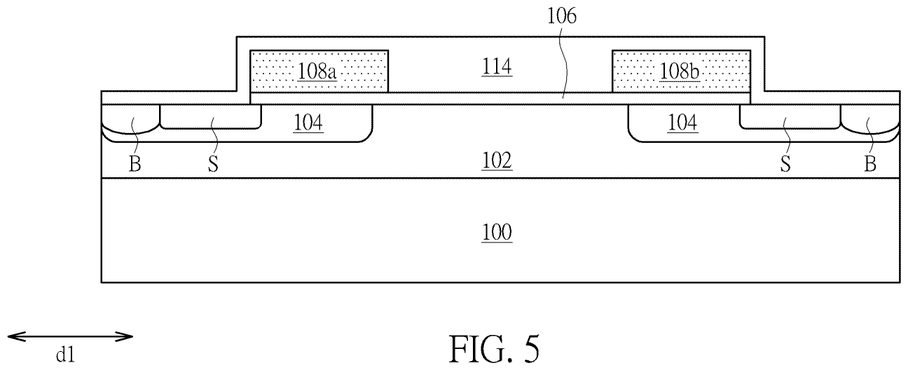

Please refer to FIG. 5. After the lower gate patterns 108a, 108b are formed, the photoresist 110 is removed, and then an isolation material layer 114 is formed on the lower gate patterns 108a, 108b and the substrate 100. The material of isolation material layer 114 may be silicon oxide, which can be formed through a CVD process. In the embodiment, the isolation material layer 114 will be filled in the space 112 between the lower gate patterns 108a, 108b to serve as the material for subsequent isolation oxide layer.

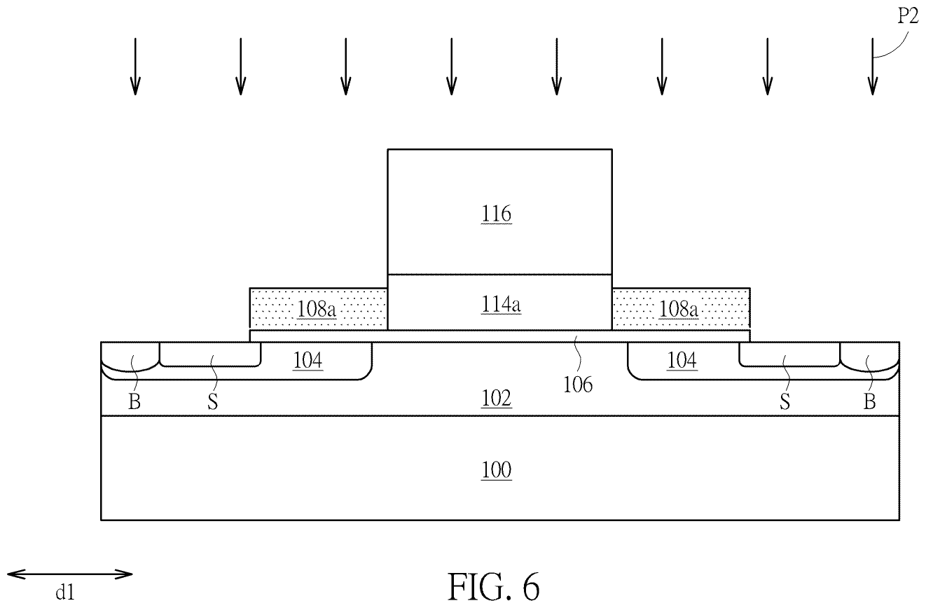

Please refer to FIG. 6. After the isolation material layer 114 is formed, a second photolithography process P2 is performed to pattern the isolation material layer 114 to form an isolation oxide layer 114a. More specifically, in this step, a photoresist 116 having the pattern of the isolation oxide layer is first formed on the isolation material layer 114, and then the photoresist 116 is used as an etching mask to perform an anisotropic etching process to remove parts of the isolation material layer 114 not shielded by the photoresist 116, until the lower gate electrode patterns 108a, 108b, the source S and the base B are exposed. The formed isolation oxide layer 114a is preferably located between the lower gate patterns 108a, 108b, and its height is higher than the height of the lower gate patterns 108a, 108b, so as to achieve the effect of isolating the two gates.

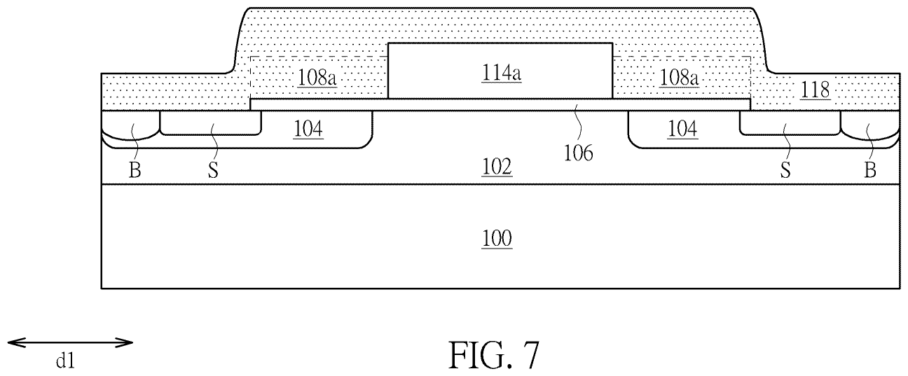

Please refer to FIG. 7. After the isolation oxide layer 114a is formed, the photoresist 116 is removed, and then a second gate material layer 118 is formed on the substrate 100. The second gate material layer 118 is made of the same material as the first gate material layer 108, which can be N-type heavily doped (N+) polysilicon and may be formed through a CVD process. The second gate material layer 118 will cover the isolation oxide layer 114a, the lower gate patterns 108a, 108b, the sources S and the bases B. In the embodiment, the second gate material layer 118 will be integrated with the lower gate patterns 108a and 108b, functioning together as a material layer for the gate to be formed later.

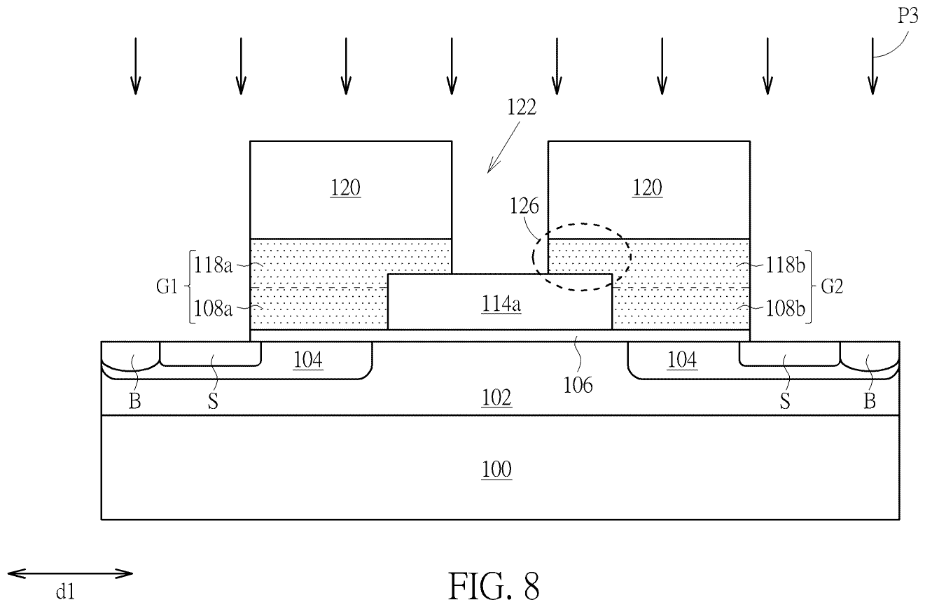

Please refer to FIG. 8. After the second gate material layer 118 is formed, a third photolithography process P3 is performed to remove parts of the second gate material layer 118 to define the upper gate patterns 118a, 118b at both sides of the device. More specifically, in this step, a photoresist 120 with an upper gate pattern is first formed on the second gate material layer 118, and then the photoresist 120 is used as an etching mask to perform an anisotropic etching process to remove the second gate material layer 118 not shielded by the photoresist 120, until the sources S and the bases B below are exposed. The formed upper gate patterns 118a, 118b will be respectively located on the lower gate patterns 108a, 108b on both sides of the isolation oxide layer 114a in the first direction d1, and their outer sidewalls are preferably flush with the sidewalls of the lower gate patterns 108a, 108b. A space 122 is formed on the isolation oxide layer 114a between the upper gate patterns 118a, 118b. In the embodiment, the formed upper gate patterns 118a, 118b are provided with extending parts 126 extending inwardly in the first direction d1 onto the isolation oxide layer 114a, but not connected with each other. Furthermore, the upper gate pattern 118a and the lower gate pattern 108a form a first gate G1, and the upper gate pattern 118b and the lower gate pattern 108b form a second gate G2. In this way, the first gate G1 and the second gate G2 are in a form of split gate, located respectively on both sides of the isolation oxide layer 114a, and the overlapping P-type well 104 below serves as a channel region for the device.

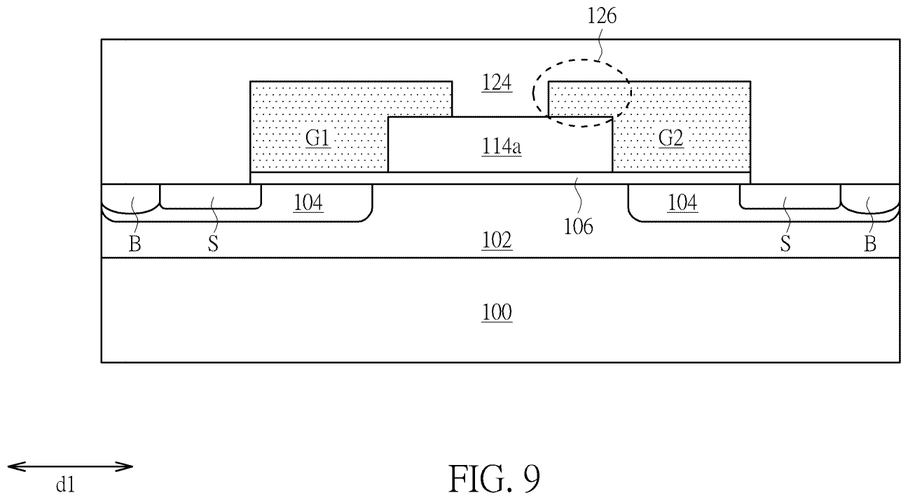

Please refer to FIG. 9. After the first gate G1 and the second gate G2 are formed, the photoresist 120 is removed, and then a passivation layer 124 is formed on the first gate G1, the second gate G2 and the substrate 100. The passivation layer 124 may be made of silicon oxide through a CVD process. In the embodiment, the passivation layer 124 covers the entire first gate G1 and the second gate G2 and fills the space 122 between the two extending parts 126 to provide a protection effect. The passivation layer 124 can also isolate the first gate G1 and the second gate G2 from the source contact metal 128 to be formed subsequently.

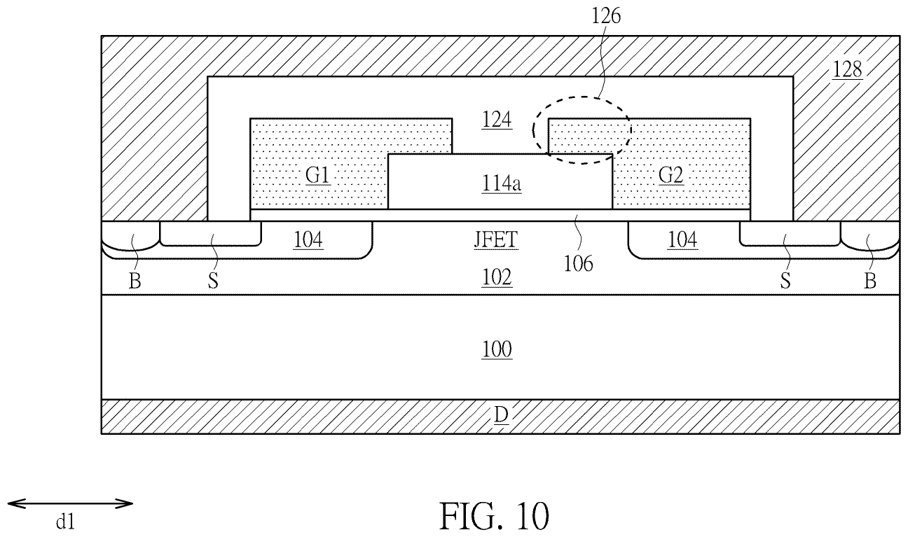

Please refer to FIG. 10. After the passivation layer 124 is formed, a source contact metal 128 is formed above the passivation layer 124. More specifically, in this step, a photolithography process is first performed to remove parts of the passivation layer 124 to expose parts of the sources S and the bases B on the substrate 100. Thereafter, a material layer for source contact metal is formed on the patterned passivation layer 124 with material like aluminum (Al), nickel (Ni), gold (Au) and other metals with high conductivity through a PVD process. Lastly, a photolithography process is performed to pattern the source contact metal material layer into source contact metal 128. The formed source contact metal 128 will be electrically connected with the sources S and the bases B on the substrate 100 to connect these terminals to a reference voltage. In some embodiments, the source S and the bases B on both sides of the device may also be connected to the reference voltage through their respective source contact metals. On the other hand, a corresponding drain contact metal D will also be formed on the back side of the substrate, with a process the same as the one of source contact metal 128, ex. PVD process. The material may also be aluminum (Al). Nickel (Ni), gold (Au) and other metals with high conductivity. In the present invention, the drain contact metal D may also be formed before or after the source contact metal 128, but is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A SiC MOSFET, comprising:
a SiC substrate;
a gate oxide layer on said SiC substrate;
an isolation oxide layer on said gate oxide layer;
two gates respectively at both sides of said isolation oxide layer in a first direction on said gate oxide layer, wherein said two gates are both provided with an extending part extending in said first direction onto said isolation oxide layer;
two sources respectively at both sides of said gate oxide layer in said first direction in said SiC substrate; and
a drain contact metal on a side of said SiC substrate opposite to said gate oxide layer.

2. The SiC MOSFET of claim 1, further comprising two bases respectively at two outer sides of said two sources in said first direction in said SiC substrate and in direct contact with said two sources respectively.

3. The SiC MOSFET of claim 2, wherein said two bases are P-type heavily doped regions.

4. The SiC MOSFET of claim 1, wherein said two sources are N-type heavily doped regions.

5. The SiC MOSFET of claim 1, further comprising two P-type wells in said SiC substrate at both sides of said isolation oxide layer in said first direction, wherein said two sources are in said two P-type wells, respectively.

6. The SiC MOSFET of claim 1, further comprising an N-type lightly doped drift region in said SiC substrate, wherein said gate oxide layer and said two sources are on said N-type drift region.

7. The SiC MOSFET of claim 1, wherein a material of said two gates is N-type heavily doped polysilicon.

8. The SiC MOSFET of claim 1, wherein said drain is a metal layer.

9. The SiC MOSFET of claim 1, further comprising a passivation layer covering said two gates and said SiC substrate.

10. The SiC MOSFET of claim 9, further comprising a source contact metal on said passivation layer and connecting said two sources.

11. A method of manufacturing a SiC MOSFET, comprising:
providing a SiC substrate with two sources facing each other in a first direction;
forming a gate oxide layer on said SiC substrate between said two sources;
forming a first gate material layer on said gate oxide layer;
performing a first photolithography process to pattern said first gate material layer into two lower gate patterns, said two lower gate patterns are respectively on edge portions of said gate oxide layer at both sides in said first direction;
forming an isolation oxide layer between said two lower gate patterns;
forming a second gate material layer on said two lower gate patterns and said isolation oxide layer; and
performing a second photolithography process to pattern said second gate material layer into two upper gate patterns, said two upper gate patterns are respectively on said two lower gate patterns and both provided with an extending parts extending inwardly in said first direction onto said isolation oxide layer, and said two upper gate patterns and corresponding said two lower gate patterns form a first gate and a second gate, respectively.

12. The method of manufacturing a SiC MOSFET of claim 11, further comprising forming a drain contact metal on a side of said SiC substrate opposite to said gate oxide layer.

13. The method of manufacturing a SiC MOSFET of claim 11, further comprising forming two bases respectively in said SiC substrate at two outer sides of said two sources in said first direction, and said two base are in direct contact with corresponding said two sources, respectively.

14. The method of manufacturing a SiC MOSFET of claim 11, further comprising forming two P-type wells in said SiC substrate at both sides of said isolation oxide layer in said first direction, wherein said two sources are respectively in said two P-type wells.

15. The method of manufacturing a SiC MOSFET of claim 11, further comprising forming an N-type lightly doped drift region in said SiC substrate, wherein said gate oxide layer and said two sources are on said N-type drift region.

16. The method of manufacturing a SiC MOSFET of claim 11, wherein steps of forming said isolation oxide layer between said two lower gate patterns comprise:
forming an isolation material layer on said two lower gate patterns and said SiC substrate; and
performing a third photolithography process to remove said isolation material layer that is not between said two lower gate patterns.

17. The method of manufacturing a SiC MOSFET of claim 11, further comprising forming a passivation layer covering said first gate, said second gate and said SiC substrate.

18. The method of manufacturing a SiC MOSFET of claim 17, further comprising forming a source contact metal on said passivation layer, and said source contact metal connects said two sources.
